(19) United States
(12) Patent Application Publication
(10) Pub. No.: US 2013/0014798 A1
(43) Pub. Date: Jan. 17, 2013

(54) THERMOELECTRIC CONVERSION ELEMENT

(71) Applicants: Akinori NISHIDE, Kokubunji (JP); Yosuke Kurosaki, Hachioji (JP); Jun Hayakawa, Hino (JP); Shin Yabuuchi, Musashino (JP); Masakuni Okamoto, Tokyo (JP)

(72) Inventors: Akinori NISHIDE, Kokubunji (JP); Yosuke Kurosaki, Hachioji (JP); Jun Hayakawa, Hino (JP); Shin Yabuuchi, Musashino (JP); Masakuni Okamoto, Tokyo (JP)

(21) Appl. No.: 13/546,008

(22) Filed: Jul. 11, 2012

(30) Foreign Application Priority Data
Jul. 11, 2011 (JP) 2011-152460

(51) Int. Cl. H01L 35/28

(52) U.S. Cl. 136/205; 136/224

(57) ABSTRACT

A thermoelectric conversion element is provided as an element module with improved utility having an enhanced performance index and utilizing Fe₂VAl type alloy thin-film under the condition of the drop in thermal conductivity. The structure of thermoelectric conversion element is comprised of a conductive buffer layer and plural repeating stages of single structures including thermoelectric conversion material layer and a conductive buffer layer, over a buffer layer formed on a substrate; and each of the thermoelectric conversion material layers is comprised of Full-Heusler alloy or Full-Heusler alloy thin film in a thickness range between 1 nm to 200 nm.

### CLAIM OF PRIORITY

The present application claims priority from Japanese patent application JP 2011-152460 filed on Jul. 11, 2011, the content of which is hereby incorporated by reference into this application.

### CROSS-REFERENCE TO RELATED APPLICATION

This application is related to U.S. application Ser. No. 13/338,740 filed on Dec. 28, 2011, the disclosure of which is hereby incorporated by reference.

### BACKGROUND

The present invention relates to a thin-film thermoelectric conversion element and a manufacturing method for that thin-film thermoelectric conversion element.

In recent years there has been increasing international concern over the issue of reducing carbon dioxide which is a substance causing the global warming phenomenon. Continuous progress is being made in technical innovations for shifting from resource energy that discharges large quantities of carbon dioxide, to reusable next generation energy such as natural energy and thermal energy. Next generation energy technology candidates includes technology utilizing natural energy such as solar power and wind power, and reusable technology for reutilizing the lost portion of primary energy such as heat and vibration emitted from using resource energy. Though conventional resource energy is a centralized energy mainly in the form of large-scale electrical generating facilities; next generation energy is featured by an uneven distribution of both natural energy and reusable energy. In current energy utilization, the energy that is waste-discharged without being used amounts to approximately 60% of primary energy and that amount is mainly in the form of waste heat. Therefore, what is needed besides increasing the proportion of next generation energy among primary energy is improved energy reutilization technology and in particular, better power conversion technology for waste heat energy. Waste heat is generated in all manner of situations so reutilizing waste heat energy requires an electrical generating system with a high degree of universality in all types of installation formats. Contriving such a generating system requires developing thermoelectric conversion materials possessing high electromotive force and in a space-saving format such as film.

This thermoelectric conversion material is an element utilized for thermoelectric cooling by using the Peltier effect and generating thermoelectric power by way of the Seebeck effect. These elements generally possess a structure where plural P-type thermoelectric material and plural N-type thermoelectric material that is alternately arrayed and coupled in series.

The currently used thermoelectric conversion material for actual applications is bismuth telluride (Bi₂Te₃). The conversion efficiency of bismuth telluride is high but both bismuth and telluride are expensive, and tellurium is toxic so bismuth telluride is not a suitable choice in terms of the goals of mass production, low-cost, and reducing the load on the environment. So a substitute high-efficiency thermoelectric conversion material is needed as a substitute for bismuth telluride (Bi₂Te₃). These circumstances have focused attention on Fe₂VAl-based alloy as a potential thermoelectric conversion material that is both non-toxic and inexpensive.

Methods for producing these thermoelectric conversion materials involved fusing or sintering by heating the raw material, and mechanically processing (cutting out) the material into a block shape. The advantage provided by this method is that the crystalline structure and elemental composition of the crystal can be controlled. However, most thermoelectric conversion materials have low mechanical strength so that intricate and precise processing is difficult, and achieving a thin and compact material was impossible. Moreover another problem was that the processing to cut-out the block had a low product yield. These circumstances served to focus attention on methods for manufacturing thermoelectric conversion material into thin film. A thermoelectric conversion material formed into a thin film can be formed into a thin-film thermoelectric conversion material possessing a fine and intricate structure, and extremely tiny and thin thermoelectric conversion elements can be made. These tiny and thin thermoelectric conversion elements could be mounted even in narrow spaces impossible for block-shaped elements to fit. A high-efficiency, thin-film thermoelectric conversion element suitable for practical use is therefore needed.

Japanese Unexamined Patent Application Publication No. 2005-277343 discloses a thermoelectric conversion element utilizing an Fe₂VAl-based thermoelectric material thin film deposited over a heated substrate. The disclosed element is a 5 μm thick N-type thermoelectric material sections and P-type thermoelectric material sections alternately arrayed in a zigzag pattern over a flat substrate. The thickness of the thermoelectric material thin film is preferably between 0.1 to 100 μm.

### SUMMARY

The performance index for thermoelectric conversion material is typically a dimensionless quantity called XT, and is given as follows.

$$ZT = \frac{{S}^{2}}{κ ρ} T \qquad ( Formula 1 )$$

Here, S denotes the Seebeck coefficient, κ is the thermal conductivity, ρ is the resistivity, and T equals the room temperature (300K). The larger the Seebeck coefficient, and the smaller the thermal conductivity and electrical resistivity, the larger the performance index becomes. The Seebeck coefficient and the electrical resistivity are physical quantities determined by the electron state of the material. According to Mott's formula, the Seebeck coefficient has a relation as shown next.

$$S ∝ \frac{1}{N ( {E}_{F} )} {( \frac{\partial N ( E )}{\partial E} )}_{E ∼ {E}_{F}} \\ E \text{:} binding energy \\ N \text{:} density of states \qquad ( Formula 2 )$$

According to formula 2, the Seebeck coefficient is inversely proportional to the absolute value of the density of states in the Fermi level, and is proportional to that energy gradient. Therefore, a material with a small density of states (hereafter DOS) in the Fermi level and whose DOS rise fluctuates drastically signifies a material with a high Seebeck coefficient. Moreover in regards to electrical resistivity has the following relation.

$$\frac{1}{ρ} ∝ {λ}_{F} {v}_{F} N ( {E}_{F} ) \qquad ( Formula 3 )$$

Here. λ_{F} and ν_{F} denote the mean free path and velocity of electrons at the Fermi level. This relation is inversely proportional to DOS of formula 3 so the electrical resistivity is small when there is a Fermi level where DOS of the absolute value is at a large energy position.

The thermoelectric conversion material of Fe₂VAl-based alloy possesses a pseudogap band structure. A pseudogap band structure is a matter or material system with an electronic state where the DOS in the vicinity of the Fermi level has drastically dropped. One feature of the Fe₂VAl-based alloy band structure is said to be behavior as a rigid band model where only the Fermi level energy position changes and also that no significant fluctuations in the band structure occur when the composition ratio of the compound is changed. Therefore, by changing the composition ratio of the compound or changing the composition of the compound for hole doping or electron doping, the Fe₂VAl-based alloy can control the Fermi level at the energy position to make steep changes in DOS and moreover attain an optimal absolute value for DOS for optimizing the relation between the Seebeck coefficient and resistivity. The above DOS changes and optimal values can be achieved in both a P-type and N-type matter system.

Under current circumstances however, the FeiVAl-based compound has large thermal conductivity near that of metal at room temperatures and higher and is still far away from attaining a practical performance index figure.

In view of the above problems and from results of extensive research, the present invention has the object of providing a thermoelectric conversion element as an element module with improved utility that possesses an enhanced performance index by utilizing the drop in thermal conductivity in Fe₂VAl-besed alloy thin-film as an operating condition.

A representative example of the thermoelectric conversion element of the present invention is featured in including a buffer layer, a thermoelectric conversion material layer, and an electrode layer laminated over a substrate, and in which the thermoelectric conversion material layer is a thin film in a range from 1 nm to 200 nm in film thick comprised of Full-Heusler alloy or an alloy with elements replaced from Full-Heusler alloy.

Another feature of the present invention is a thermoelectric conversion element comprised of a plurality of layers of the above described thermoelectric conversion material layer and possessing a structure to obtain a total electromotive force that is the sum of the electromotive force in each layer. Specific features are the points that a plurality of single-unit structures comprised of laminated thermoelectric conversion material layer and a conductive buffer layer, are repeatedly deposited (formed); and that a lower electrode is coupled to the lowermost buffer layer for extracting the summed output of the electromotive force for each of the thermoelectric conversion material layers when a temperature gradient is applied in a direction perpendicular to the film plane, and that an upper electrode is deposited over the uppermost thermoelectric conversion material layer.

Another specific feature is the point that the invention is comprised of multilayer structure layer comprised of a plurality of N-type thermoelectric conversion material layers and insulator layers alternately and repetitively formed with an insulator layer interposed between them, over a buffer layer deposited over the substrate; and a lower electrode coupled to one end of an N-type thermoelectric conversion material layer within the single-unit structure of the lowermost section; a plurality of coupling electrodes are coupled successively and moreover at alternative positions at both ends of the thermoelectric conversion material layers laminated adjacent to the upper section, a coupling electrode for example couples the other end of the N-type thermoelectric conversion material layer to one end of the P-type thermoelectric conversion material layers; and a coupling electrode couples the other end of that P-type thermoelectric conversion material layer (however the end side where the above described lower electrode is coupled) to one end of the P-type thermoelectric conversion material layer above that coupled P-type thermoelectric conversion material layer; and an upper electrode is then coupled to the P-type thermoelectric conversion material layer within the single-unit structure of the uppermost section.

The material for the above described thermoelectric conversion material layer was Full-Heusler alloy or an alloy with elements replaced from Full-Heusler alloy, however the term Fe₂VAl-based alloy may also be utilized. Besides Fe₂VAl-based alloy other typical compounds for the material may include Fe₂TiSn. Fe₂TiSi, or Fe₂NbAl; and more specifically an alloy whose composition is Fe₂N₁₋ₓMₓX₁₋ₓYₓ (however, N or M=V, Nb, Ti, Mo, W, Zr, and also X or Y═Al, Si, Sn, Ge).

The Seebeck coefficient and the electrical conductivity of the Fe₂VAl-based alloy can be optimally controlled by replacing the elements to alter the electron state. However, at room temperatures, the Fe₂VAl-based alloy has properties resembling those of metal so that the thermal conductivity becomes large. Attaining ZT=2 which is said to be the boundary for practical use requires lowering this thermal conductivity.

The thermal conductivity κ is expressed as follows.

$$\begin{matrix}κ = {k}_{f} \times {C}_{p} \times ς & ( Formula 4 ) \\ {k}_{f} = \frac{{d}^{2}}{{τ}_{f}} & ( Formula 5 )\end{matrix}$$

Here, ζ or zeta is the density of the material, d is the sample film thickness, Cₚ is the sample specific heat at constant pressure, if is the time for the heat to propagate from the rear side of the thin film sample with a thickness d to the front side. As can be understood from formula 4 and formula 5, the thinner the sample film thickness, the smaller the thermal conductivity becomes. Heat is conveyed within a substance by way of electrons or lattice vibrations. Heat propagation by way of electrons is determined by the electron density within the substance. Heat propagation by way of lattice vibration is determined by the type of element and the crystalline structure. In other words, the change in thermal conductivity induced by controlling the thickness of the thin film is a property unique to the particular substance. The Physical Review B, 82, 075418, for example reported a change in thermal conductivity characteristics relative to the film thickness of copper (Cu). In this example, one can understand that at a film thickness of 100 nm or less, the thermal conductivity is proportional to the film thickness. However, as the film thickness approaches 200 nm, this proportional relation has already been lost and that thermal conductivity relative to increased film thickness is asymptotic to bulk thermal conductivity. In other words in copper (Cu) no clear effect in reducing thermal conductivity appears even if the film thickness was reduced at the vicinity of 200 nm.

Whereupon the present inventors, sought to ascertain the thermal conductivity characteristics of Fe₂VAl-based alloy relative to changes in film thickness and verified the correct film thickness for obtaining a clear reduction in thermal conductivity. FIG. 1 shows the results derived from those thermal conductivity characteristics. These results confirmed that in Fe₂VAl-based alloy, the film thickness is proportional to thermal conductivity in a film thickness range to 200 nm, or namely that the effect from a drop in thermal conductivity relative to film thickness is clearly evident in this range. The above description therefore shows that the method for lowering thermal conductivity in the representative structure of the present invention is producing the thermoelectric conversion material Fe₂VAl-based alloy as a thin film, and that a suitable film thickness is 1 nm to 200 nm. The film thickness lower threshold value of 1 nm is equivalent to a few molecules of Fe₂Val, and is a lower threshold value that allows forming a stable and uniform alloy film.

If the film thickness range of the Fe₂VAl-based alloy could be further narrowed to 100 nm or lower, then a thin film will possess a thermal conductivity less than one-fourth that of the bulk thermal conductivity, and the performance index as a thermoelectric conversion element can be increased to a higher level. Moreover, at a film thickness of 50 nm, the value for a performance index XT was confirmed as approximately 10 times that of bulk thermal conductivity.

The present invention therefore achieves a thermoelectric conversion element possessing a high performance index by utilizing material having a small environmental load and moreover by selecting film thickness conditions and contriving a suitable structure.

### BRIEF DESCRIPTION OF THE DRAWINGS

FIG. 1 is a cross-sectional correlation diagram of the film thickness and thermal conductivity;

FIG. 2 is a cross-sectional schematic diagram of the thin-film thermoelectric conversion element of a first embodiment of the present invention;

FIG. 3 is a cross-sectional schematic diagram of the multilayer film perpendicular series type thermoelectric conversion element of a second embodiment;

FIG. 4 is a cross-sectional schematic diagram of a variation of the thermoelectric conversion element of the second embodiment;

FIG. 5 is cross-sectional schematic diagram of the multilayer internal plane series type thermoelectric conversion element of a third embodiment;

FIG. 6 is a cross-sectional schematic diagram of a variation of the thermoelectric conversion element of the third embodiment.

### DETAILED DESCRIPTION

### First Embodiment

FIG. 2 is a cross-sectional schematic diagram showing the thermoelectric conversion element of the first embodiment. A multilayer film comprised of a buffer layer 101, a thermoelectric conversion material layer 102, and an electrode layer 103 were deposited over a silicon substrate 100 formed with a thermal oxide film. Tantalum (Ta) may for example be utilized as the buffer layer 101 or Ta/MgO (film thickness of 3 nm) may be utilized. If MgO having tantalum (Ta) as an under-layer was utilized as the buffer layer then the MgO structure is a rock-salt structure. The crystalline structure is oriented towards (100). The thermoelectric conversion material layer 102 utilized Fe₂VAl as the Full-Heusler alloy.

Each layer was deposited over the silicon substrate 100 utilizing the sputtering method along with argon (Ar) gas. The tantalum (Ta) was formed as a film in an amorphous state over the heat-oxidized silicon substrate at room temperature. After forming the laminated film, the laminated film was stripped away to directly above the buffer layer 101, then the thermoelectric conversion material layer 102 and the electrode layer 103 was cut out over the buffer layer by using electron beam (EB) lithography and ion beam etching. Silicon dioxide (SiO₂) was formed as a film over the upper surface, a resist coating was applied, and electron beam (EB) lithography and ion beam etching were used in the forming process. Measuring the voltage across die electrodes showed that an electromotive force was generated when the substrate was in contact with a high-temperature section and generated a temperature gradient perpendicular to the element. Needless to say, wiring was formed in order to extract the respective voltages from the lower electrode and upper electrode.

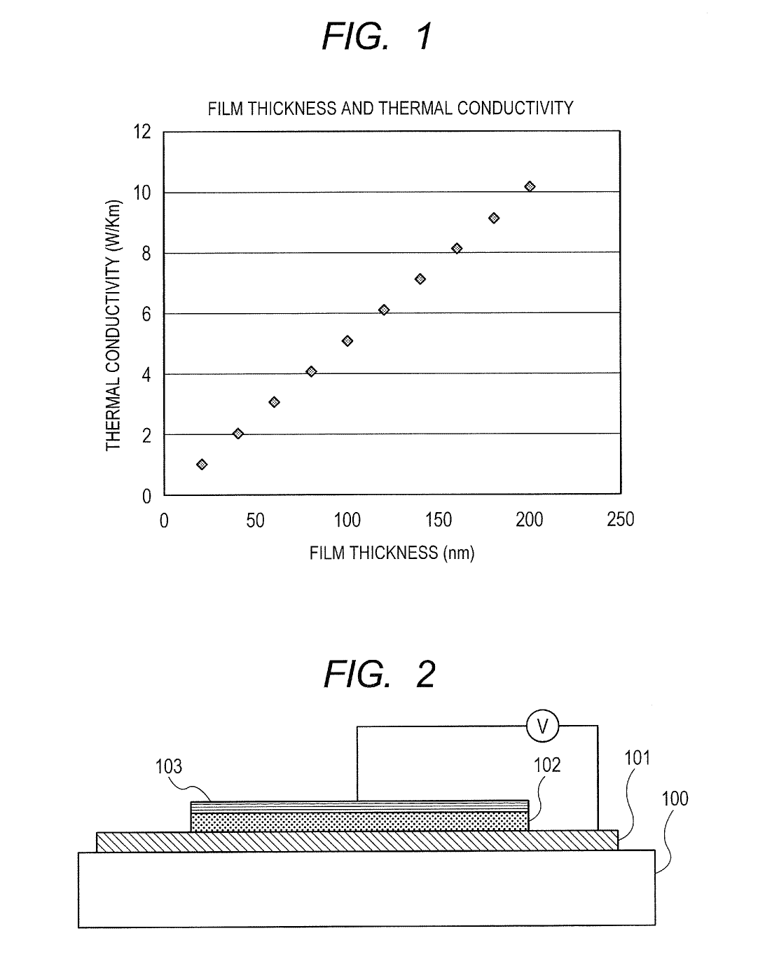

The thermal conductivity for various Fe₂Val thin-film thicknesses was found for the present embodiment. Those results are as shown in FIG. 1. Examining FIG. 1 reveals that there is a proportional relationship between the film thickness and thermal conductivity in a film thickness range of 200 nm and lower. At a film thickness of 200 nm, a thermal conductivity that is one-half that of the bulk thermal conductivity has already been attained. These results confirm the effect of lowering thermal conductivity in order to extract ample electrical generating performance in a film thickness range from 1 nm to 200 nm. At a film thickness range below 100 nm, the Fe₂Val thin-film thermal conductivity was one-fourth or less that of the bulk thermal conductivity, and the effect on the performance index as a thermoelectric conversion element increase to a still higher level. Moreover a Fe₂Val thin-film with a film thickness of 50 nm attained a performance index ZT value 10 times that of the bulk thermal conductivity and a Fe₂Val thin-film with a film thickness of 10 nm attained a XT value 50 times that of the bulk thermal conductivity.

In the example of the present embodiment, Fe₂VAl was utilized as the thermoelectric conversion material, however other material may be utilized if a Full-Heusler alloy. Namely, besides Fe₂VAl, other material may include Fe₂TiSn, Fe₂TiSi, or Fe₂NbAl, etc., or an alloy whose composition is Fe₂N₁₋ₓMₓX₁₋ₓYₓ (however N or M=V, Nb, Ti, Mo, W, Zr, and also X or Y═Al, Si, Sn, Ge) will render the same effect.

### Second Embodiment

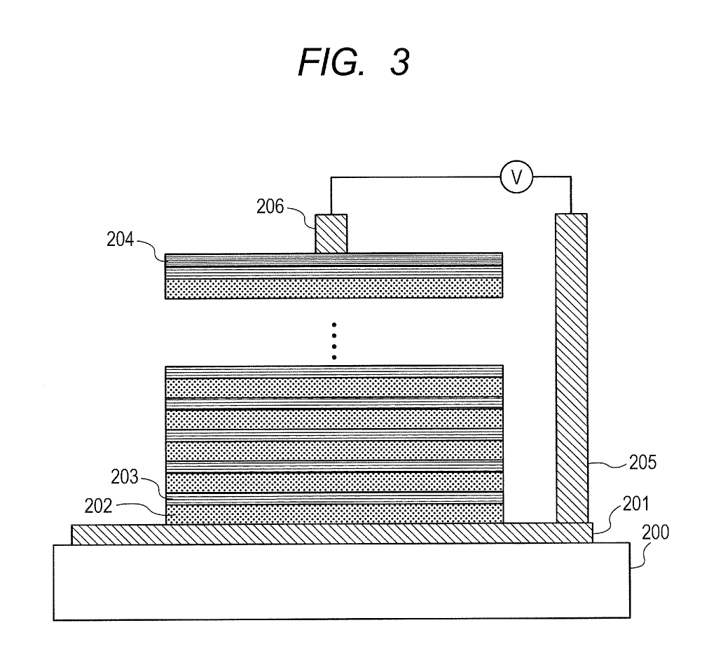

FIG. 3 is a cross-sectional schematic diagram of the thermoelectric conversion element of the second embodiment. The thermoelectric conversion element of the second embodiment has a laminated structure that includes a first buffer layer 201, a thermoelectric conversion material layer 202, and a conductive second buffer layer 203 deposited in layers over a silicon substrate 200 formed with a thermal oxide film, and a laminated structure as the film-formed electrode layer 204 formed after repeatedly laminating the thermoelectric conversion material layer 202 and conductive second buffer layer 203 single unit structures multiple times. Tantalum (Ta) was utilized in the first buffer layer 201. Silver (Ag) was utilized in the second buffer layer.

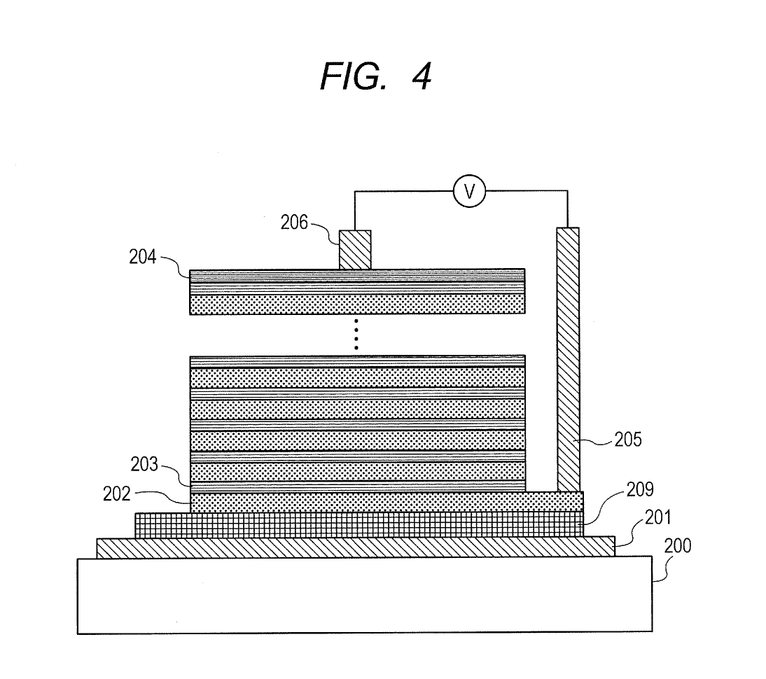

FIG. 4 shows a thermoelectric conversion element as a variation of the thermoelectric conversion element in FIG. 3. The variation in FIG. 4 differs from the structure of the second embodiment in FIG. 3, in the point that a third buffer layer 209 is interposed between the first buffer layer 201 and the thermoelectric conversion material layer 202. Here, the third buffer layer 209 utilized MgO (film thickness of 3 ran). This structure is a rock-salt structure and the crystalline structure is oriented towards (100). In both the structures in FIG. 3 and FIG. 4 the thermoelectric conversion material layer 102 utilized Fe₂VAl as the Full-Heusler alloy.

Each layer was deposited over the silicon substrate 200 utilizing the sputtering method along with argon (Ar) gas. The tantalum (Ta) was formed as a film in an amorphous state over the heat-oxidized silicon substrate at room temperature. After forming the laminated film, the laminated film was stripped away to directly above the first buffer layer 201 in FIG. 3, and stripped away to directly above the third buffer layer 209 in FIG. 4 by electron beam (EB) lithography and ion beam etching. In this way, a structure comprised of a gigantic thermoelectric conversion element pillar was made. Silicon dioxide (SiO₂) was deposited as a film over the upper surface, a resist coating applied, and electron beam (EB) lithography and ion beam etching utilized to form an electrode 205 and an electrode 206. The electrode 205 was formed coupled to the first buffer layer 201 in FIG. 3. An insulating third buffer layer 209 was interposed between the first buffer layer 201 and the thermoelectric conversion material layer 202 as shown in FIG. 4, so that the electrode 205 is formed to directly couple to the thermoelectric conversion material layer 202. When the substrate contacts a high temperature section and generated a temperature gradient perpendicular to the element, an electromotive force occurs in each thermoelectric conversion layer, and the voltage across the electrode 205 and the electrode 206 is the sum of those voltages. This voltage can be extracted as the output.

The second embodiment provides an improved performance index by lowering the thermal conductivity in thermoelectric conversion material with a film thickness in a range from 1 nm to 200 nm the same as in the first embodiment. This effect is drastically evident at film thicknesses below 100 nra. Moreover in this embodiment, the number of laminations of thermoelectric conversion material thin film can be changed to match the required voltage.

The present embodiment utilized Fe₂VAl as an example of the thermoelectric conversion material, however other material may be utilized if a Full-Heuslcr alloy. Namely, besides Fe₂VAl, other material may include Fe₂TiSn, Fe₂TiSi, or Fe₂NbAl, etc., or an alloy whose composition is Fe₂N₁₋ₓMₓX₁₋ₓYₓ (however N or M=V, Nb, Ti, Mo, W, Zr, and also X or Y═Al, Si, Sn, Ge) will render the same effect.

Besides silver (Ag), the material utilized in the second buffer layer may include: Cu, Au, Pt, Pd, Ru, Rh. Ta, W, V, Ti, and Mg.

### Third Embodiment

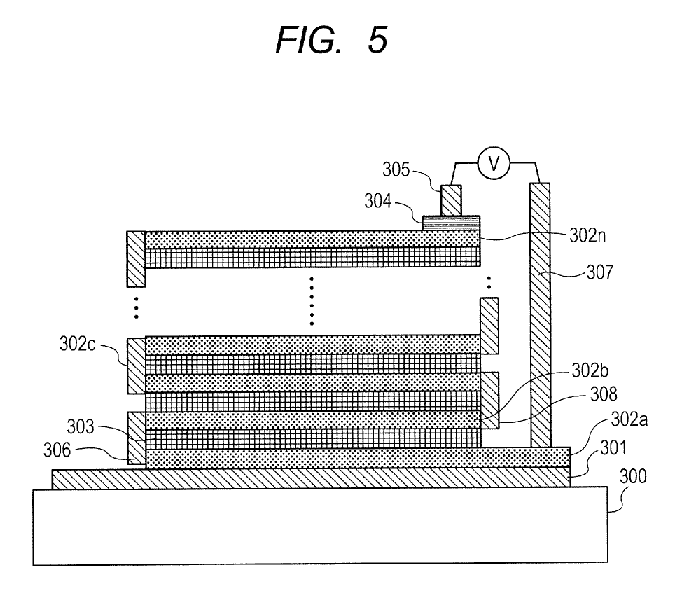

FIG. 5 is cross-sectional schematic diagram of the thermoelectric conversion element of the third embodiment. The thermoelectric conversion element of the third embodiment has a laminated structure that includes a first buffer layer 301, a thermoelectric conversion material layer 302a, and an insulator layer 303 deposited in layers over a silicon substrate 300 formed with a thermal oxide film, and the film-formed electrode layer 304 over single-unit structures comprised of thermoelectric conversion material layer and the second insulator layer repeatedly laminated multiple times. Tantalum (Ta) was utilized in the first buffer layer 301 the same as in the second embodiment in FIG. 3, and MgO was utilized in the insulation layer.

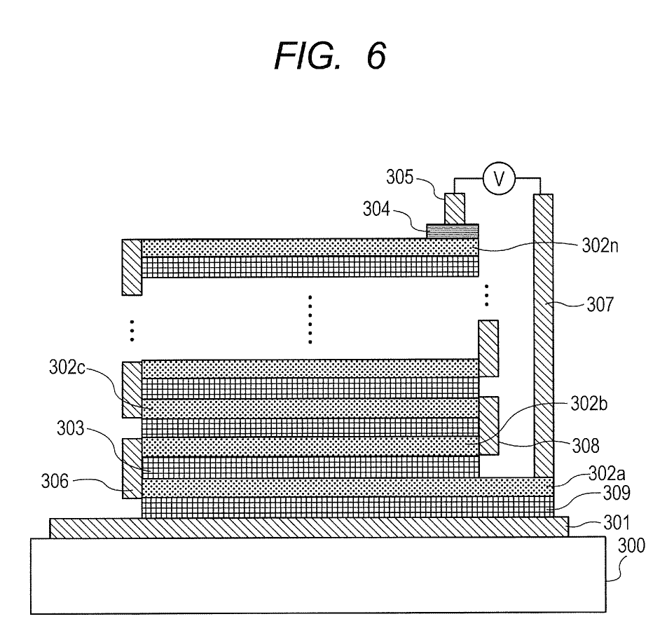

FIG. 6 shows a thermoelectric conversion element whose structure was formed as a variation of the thermoelectric conversion element in FIG. 5. In contrast to the third embodiment in FIG. 5, the variation shown in FIG. 6 is a laminated structure comprised of a second buffer layer 309 over a first buffer layer. The second buffer layer 309 is MgO (film thickness of 3 nm) having a crystal orientation (110) the same as the variation in FIG. 4. The thermoelectric conversion material is Fe₂VAl serving as the Full-Heusler alloy, the same as in the previous embodiments. However, a feature of the elements in FIG. 5 and FIG. 6 is that in the laminated structure of multiple repeating layers of single-unit structures, the thermoelectric conversion material layer 302 is N-type Fe₂VAl and P-type Fe₂VAl alternately arrayed layers. Moreover, an electrode 307 is coupled to one end of the lowest layer N-type Fe₂ VAl layer 302a, and the other opposing facing side, a coupling electrode 306 is formed coupled to the end side surface of the P-type Fe₂VAl 302b (above the N-type Fe₂VAl layer 302a). Moreover, a coupling electrode 308 is formed coupled to the end side of the N-type Fe₂VAl layer 302c (above P-type Fe₂VAl 302b) at the other end (first end side of lowermost layer of N-type Fe₂VAl layer 302a) of the P-type Fe₂VAl layer 302b. The coupling electrodes are in this way formed coupled to the Fe₂VAl layers laminated adjacent to the upper section of the Fe₂VAl layer successively and moreover alternately coupled to both opposing ends. The upper electrode 304 is deposited near the other end of the uppermost N-type Fe₂VAl layer 320n. In this embodiment also, each layer is deposited over the silicon substrate 300 utilizing the sputtering method using argon (Ar) gas. After forming the laminated film, the laminated film was stripped away to directly above the first buffer layer 302 by utilizing electron beam (EB) lithography and ion beam etching to form a laminated structure comprised of a gigantic thermoelectric conversion element pillar. After forming a coupling electrode on the side surface, silicon dioxide (SiO₂₆) was deposited as a film over the upper surface, a resist coating applied, and electron beam (EB) lithography and ion beam etching utilized to form an electrode 305 and an electrode 307

In the structure of the above third embodiment and its variation, when the substrate 300 contacts a high temperature section, a temperature gradient is generated along the internal plane of each layer in the element causing an electromotive force to occur in each layer of the Fe₂VAl. The voltages of the N-type Fe₂VAl and P-type Fe₂VAl attain opposite states. A voltage is obtained that is the sum of the electromotive forces of each Fe₂VAl layer between the electrode 305 and electrode 307 sequentially coupled by the above described coupling electrodes. The third embodiment and variation of the third embodiment are in this way thermoelectric conversion elements that generate an electromotive force when a temperature gradient is applied along the internal plane in each layer and the utilization of the element differs from the second embodiment. The same points in the first embodiment and the second embodiment also apply to the film thickness of each thermoelectric conversion layers in the present embodiment. Namely, by controlling the film thickness to lower the thermal conductivity, a performance index ZT value is attained that is definitely improved compared to bulk material Fe₂VAl which is exactly the same as previously described in the first embodiment and the second embodiment so that the practicality of the thermoelectric conversion element is improved.

The present embodiment need not utilize only Fe₂VAl as the thermoelectric conversion material and other material may be utilized if a Full-Heusler alloy. Other possibilities include Fe₂TiSn, Fe₂TiSi, or Fe₂NbAl, etc. Still other possibilities are alloys whose composition is Fe₂N₁₋ₓMₓX₁₋ₓYₓ (however, N or M=V, Nb, Ti, Mo, W, Zr, and also X or Y═Al, Si, Sn, Ge) will render the same effect.

Besides MgO, the insulator layer 303 may also utilize Al₂O₃, and SiO₂, etc.

The present invention therefore provides a thermoelectric conversion element posing a low environmental load, ideal for mass production and moreover compact and with high performance and capable of practical use in many areas.

What is claimed is:

1. A thermoelectric conversion element comprising:
a substrate;
a buffer layer formed over the substrate;
a thermoelectric conversion material layer; and
an electrode layer,
wherein the thermoelectric conversion material layer is a Full-Heusler alloy or an alloy with elements replaced from Full-Heusler alloy and whose film thickness is in a range from 1 nm to 200 nm.

2. The thermoelectric conversion element according to claim 1, wherein the thickness of the thermoelectric conversion material layer is in a range below 100 nm.

3. The thermoelectric conversion element according to claim 1, wherein a temperature gradient is applied within the plane of the sample to generate an electromotive force.

4. The thermoelectric conversion element according to claim 1, wherein the buffer layer includes tantalum (Ta) or a laminated structure of Ta and MgO.

5. A thermoelectric conversion element comprising:
a substrate;
a first buffer layer deposited over the substrate;
a multi-layer structure layer formed repeatedly from plural single-unit structures including a thermoelectric conversion material layer and a conductive second buffer layer; and
an upper electrode layer,
wherein the thermoelectric conversion material layer is a Full-Heusler alloy or an alloy with elements replaced from Full-Heusler alloy and is a thin film with a thickness between 1 nm or more and 200 nm or less; and obtains an electromotive force that is the sum of the electromotive force occurring in each thermoelectric conversion material layer according to the temperature gradient along the perpendicular direction in each layer.

6. The thermoelectric conversion element according to claim 5,
wherein the thermoelectric conversion material layer is a Full-Heusler alloy or an alloy with elements replaced from the Full-Heusler alloy combining Fe, one or more elements selected from among Nb, V, Ti, Mo, W, Zr, and one or more elements selected from Al, Sn, Si, Ge, and
wherein the second buffer layer comprising one or more metals selected from among Ag, Cu, Au, Pt, Pd, Ru, Rh, Ta, W, V, Ti, and Mg.

7. The thermoelectric conversion element according to claim 5, further comprising:
an insulating third buffer layer interposed between the first buffer layer and the multi-layer structure layer.

8. A thermoelectric conversion element comprising:
a substrate;
a buffer layer deposited over the substrate;
a multi-layer structure layer containing plural, alternate and repetitive laminations of N-type thermoelectric conversion material layer and P-type thermoelectric conversion material layer with insulator layers interposed therebetween; and
an upper electrode,
wherein the N-type thermoelectric conversion material layer and P-type thermoelectric conversion material layer in the multi-layer structure layer are a Full-Heusler alloy or an alloy with elements replaced from Full-Heusler alloy and whose film thickness is in a range from 1 nm to 200 nm, and
wherein a lower electrode coupled to one end of the lowermost N-type thermoelectric conversion material layer in the multi-layer structure layer; a first coupling electrode for coupling to thermoelectric conversion material layer adjoining the upper side of that lowermost N-type thermoelectric conversion material layer, coupled to the other end on the opposite side on one end; a second coupling electrode for coupling to thermoelectric conversion material layer adjoining the further upper side, coupled to the other end on the opposite side of the first coupling electrode on the thermoelectric conversion material layer adjoining the upper side each of the coupling electrodes couples the following thermoelectric conversion material layers successively to the lowermost thermoelectric conversion material layer; thereby obtaining an electromotive force which is the sum of the electromotive forces occurring in each thermoelectric conversion material layer according to the temperature gradient along the internal plane in each layer.

9. The thermoelectric conversion element according to claim 8,
wherein each of the P-type thermoelectric conversion material layers and N-type thermoelectric conversion material layers is a Full-Heusler alloy or an alloy with elements replaced from the Full-Heusler alloy combining Fe, one or more elements selected from among V, Ti, Mo, W, Zr, and one or more elements selected from Al, Sn, Si, and
wherein the insulation layer includes any of MgO, Al₂O₃, or SiO₂.

10. The thermoelectric conversion element according to claim 8, wherein a second buffer layer is interposed between the first buffer layer and thermoelectric conversion material.
